(19) United States
(12) Patent Application Publication
(10) Pub. No.: US 2018/0190853 A1
(43) Pub. Date: Jul. 5, 2018

(54) METHOD FOR MANUFACTURING HETEROJUNCTION WITH INTRINSIC THIN LAYER SOLAR CELL

(71) Applicant: NATIONAL TAIWAN NORMAL UNIVERSITY, Taipei City (TW)

(72) Inventors: MIN-HUNG LEE, TAIPEI CITY (TW); CHIH-YU CHEN, TAOYUAN CITY (TW); GING-RUE LIOU, TAIPEI CITY (TW); SHU-TONG CHANG, TAICHUNG CITY (TW)

(21) Appl. No.: 15/846,463

(22) Filed: Dec. 19, 2017

(30) Foreign Application Priority Data
Dec. 30, 2016 (TW) 105144314

(51) Int. Cl. H01L 31/0747; H01L 31/18

(52) U.S. Cl. CPC H01L 31/0747; H01L 31/1804

(57) ABSTRACT

A Heterojunction with Intrinsic Thin layer (HIT) solar cell has a crystalline Si substrate, an intrinsic amorphous Si layer, a doped amorphous Si layer, a transparent conductive layer and two electrode layers. The intrinsic amorphous Si layer disposed between the doped amorphous Si layer and the crystalline silicon substrate contacts the doped amorphous Si layer and the crystalline silicon substrate. Each of the intrinsic amorphous Si layer and the doped amorphous Si layer has the thickness less than 50 nm. The intrinsic amorphous Si layer and the doped amorphous Si layer are both made by electron beam evaporation. The transparent conductive layer is formed on the doped amorphous Si layer. The two electrode layers are formed on the transparent conductive layer and the crystalline silicon substrate respectively. The crystalline silicon substrate is disposed between the two electrode layers.

### BACKGROUND

### 1. Technical Field

The present disclosure relates to a method for manufacturing a solar cell, in particular, to a method for manufacturing a Heterojunction with Intrinsic Thin layer (HIT) solar cell.

### 2. Description of Related Art

The silicon based solar cell now is the widely used solar cell, which uses the photovoltaic effect to produce the electric energy. When the light beam illuminates the silicon based solar cell, the silicon based solar cell absorbs partial photons of the light beam to generate a plurality of electrons and holes, and the built-in electric field induced by the PN junction can make these electrons and holes drift to the N-type region and P-type region respectively so as to form an open-circuit voltage, i.e. a photovoltage.

The higher the open-circuit voltage is, the higher the energy conversion efficiency of the silicon based solar cell is, and thus the major research issue of most manufacturers is how to raise the energy conversion efficiency of the silicon based solar cell.

### SUMMARY

The present disclosure provides a method for manufacturing a HIT solar cell, so as to increase an open-circuit voltage.

The present disclosure provides a method for manufacturing a Heterojunction with Intrinsic Thin layer (HIT) solar cell. In the method, firstly, a crystalline Si substrate having a first surface and a second surface opposite to the first surface is provided. Next, acidic liquid is used to clean the first surface. Then, electron beam evaporation is performed to sequentially form an intrinsic amorphous Si layer and a doped amorphous Si layer on the first surface, wherein the intrinsic amorphous Si layer contacts the doped amorphous Si layer and the crystalline Si substrate, and is disposed between the doped amorphous Si layer and the crystalline Si substrate, the intrinsic amorphous Si layer has a thickness of 5 nm to 50 nm, and the doped amorphous Si layer has a thickness of 10 nm to 100 nm. Next, a transparent conductive layer is formed on the doped amorphous Si layer. Next, a first electrode layer is formed on the transparent conductive layer, wherein the first electrode layer exposes at least one portion of the transparent conductive layer. A second electrode layer is formed on the second surface, wherein the crystalline Si substrate is disposed between the first electrode layer and the second electrode layer. After forming the first electrode layer and the second electrode layer, rapid thermal annealing is performed for the intrinsic amorphous Si layer, the doped amorphous Si layer and the crystalline Si substrate in atmosphere gas, wherein the atmosphere gas comprises hydrogen gas.

According to the above features, the acidic liquid is composed of nitric acid, acetic acid and hydrofluoric acid.

According to the above features, a weight ratio of the nitric acid, the acetic acid and the hydrofluoric acid associated with the acidic liquid is 23:14:4.5.

According to the above features, using the acidic liquid to clean the first surface is to soak the crystalline Si substrate in the acidic liquid, and a time of soaking the crystalline Si substrate in the acidic liquid is 2-5 minutes.

According to the above features, a temperature of the rapid thermal annealing is 200-400 centigrade degrees.

According to the above features, a temperature of the rapid thermal annealing is 400-600 centigrade degrees.

According to the above features, the transparent conductive layer is formed by physical vapor deposition.

According to the above features, the physical vapor deposition is sputtering, and a base pressure of the sputtering is 10⁻⁵-10⁻⁶ torr.

According to the above features, a base pressure of the electron beam evaporation is less than 5×10⁻⁶ torr.

According to the above features, both of the first electrode layer and the second electrode layer are formed by the electron beam evaporation.

According to the above features, the atmosphere gas further comprises nitrogen gas, and in the atmosphere gas, a concentration of the nitrogen gas is larger than that of the hydrogen gas.

Accordingly, the interface between the intrinsic amorphous Si layer and the crystalline Si substrate form a junction between the monocrystalline Si and the amorphous Si with different energy bands, so as to reduce the probability of trapping the charge carrier and to raise the open-circuit voltage.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1 is a schematic diagram showing a structure of a crystalline Si substrate in a method for manufacturing a HIT solar cell according to one embodiment of the present disclosure.

FIG. 2 is a schematic diagram showing a structure of three stacked layers in a method for manufacturing a HIT solar cell according to one embodiment of the present disclosure.

FIG. 3 is a schematic diagram showing a structure of four stacked layers in a method for manufacturing a HIT solar cell according to one embodiment of the present disclosure.

FIG. 4 is a schematic diagram showing a structure of multiple stacked layers in a method for manufacturing a HIT solar cell according to one embodiment of the present disclosure.

### DESCRIPTION OF THE EXEMPLARY EMBODIMENTS

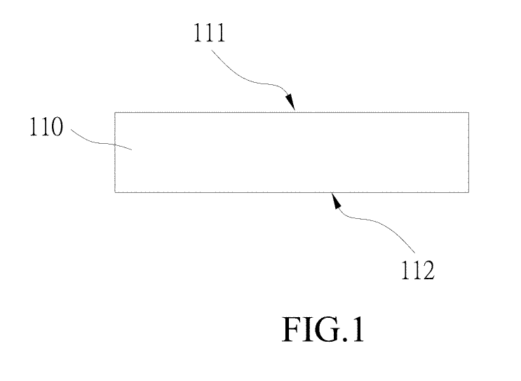

Referring FIG. 1 through FIG. 4 simultaneously, they are schematic diagrams respectively showing structures of a crystalline Si substrate, three stacked layers, four stacked layers and multiple stacked layers in a method for manufacturing a HIT solar cell according to one embodiment of the present disclosure. Firstly, refer to FIG. 1, and in the method for manufacturing the HIT solar cell of the embodiment, firstly, a crystalline Si substrate 110 is provided, wherein the crystalline Si substrate 110 is a Si wafer being sliced or not sliced, and the composition of the Si wafer can be monocrystalline Si. Thus, the crystalline Si substrate 110 can be monocrystalline Si substrate. In addition, the crystalline Si substrate 110 can be a doped Si wafer, such as an N-type doped Si wafer or a P-type dope Si wafer.

Next, acidic liquid is used to clean the crystalline Si substrate 110. The crystalline Si substrate 110 has a first surface 111 and a second surface 112, wherein the second surface 112 is disposed opposite to the first surface 111, and the acidic liquid is mainly used to clean the first surface 111. The acidic liquid can comprise nitric acid, acetic acid and hydrofluoric acid. Alternatively, the acidic liquid is composed of nitric acid, acetic acid and hydrofluoric acid, wherein a weight ratio of the nitric acid, the acetic acid and the hydrofluoric acid associated with the acidic liquid is 23:14:4.5. The manner of using the acidic liquid to clean the first surface 111 can comprise step of soaking the crystalline Si substrate 110 in the acidic liquid. A time of soaking the crystalline Si substrate 110 in the acidic liquid is 2-5 minutes, for example, the crystalline Si substrate 110 is soaked in the acidic liquid for about 2 minutes or about 5 minutes.

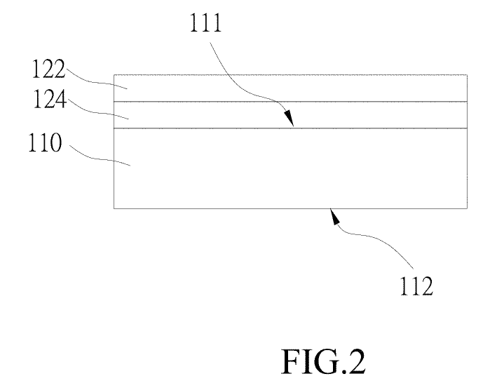

Still refer to FIG. 2. After cleaning the first surface 111, electron beam evaporation (E-Beam Evaporation) is performed to sequentially form intrinsic amorphous Si layer (i-a-Si layer) 124 and a doped amorphous Si layer 122 on the first surface 111. Thus, the intrinsic amorphous Si layer 124 is formed on the first surface 111, and the doped amorphous Si layer 122 is formed on the intrinsic amorphous Si layer 124. That is, the intrinsic amorphous Si layer 124 is disposed between the doped amorphous Si layer 122 and the crystalline Si substrate 110, and contacts the doped amorphous Si layer 122 and the crystalline Si substrate 110.

Each of the intrinsic amorphous Si layer 124 and the doped amorphous Si layer 122 has a thickness less than 50 nm. For example, the intrinsic amorphous Si layer 124 has the thickness of 5-50 nm, such as 10 nm. The doped amorphous Si layer 122 has a thickness of 10-100 nm, such as 20 nm. Compared with a thickness of the crystalline Si substrate 110 (for example, 200 μm), both of the thicknesses of the intrinsic amorphous Si layer 124 and the doped amorphous Si layer 122 are very thin. In addition, the doped type of the crystalline Si substrate 110 can be different from that of the doped amorphous Si layer 122. Specifically, when the crystalline Si substrate 110 is N-type doped, the doped amorphous Si layer 122 is P-type doped. Alternatively, when the crystalline Si substrate 110 is P-type doped, the doped amorphous Si layer 122 is N-type doped.

A base pressure of the electron beam evaporation can be less than 5×10⁻⁶ torr, so the base pressure is approximate to high vacuum or ultra-high vacuum. In addition, during the period of forming the doped amorphous Si layer 122 and the intrinsic amorphous Si layer 124, the doped amorphous Si layer 122, the intrinsic amorphous Si layer 124 and the crystalline Si substrate 110 are kept in the vacuum environment without contacting air or atmosphere. For example, the doped amorphous Si layer 122 and the intrinsic amorphous Si layer 124 are formed in the same chamber, and that is, the intrinsic amorphous Si layer 124 and the crystalline Si substrate 110 are formed in situ. Thus, the thinner doped amorphous Si layer 122 and the thinner intrinsic amorphous Si layer 124 are not oxidized when being exposed in atmosphere or air.

Since both of the intrinsic amorphous Si layer 124 and the doped amorphous Si layer 122 are formed by performing the electron beam evaporation, compared with the convention solar cell which chemical vapor deposition (CVD) is used, both of the intrinsic amorphous Si layer 124 and the doped amorphous Si layer 122 have lower manufacturing cost, and thus the manufacturing cost of the HIT solar cell can be reduced.

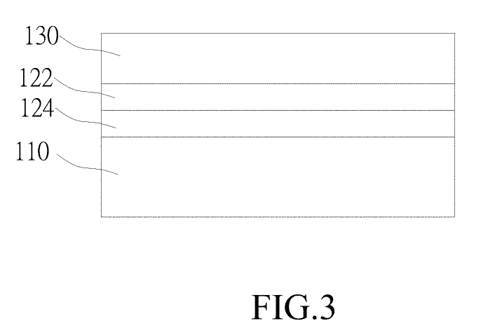

Still refer to FIG. 3. Next, a transparent conductive layer 130 is formed on the doped amorphous Si layer 122, wherein the transparent conductive layer 130 can be an indium tin oxide layer (ITO layer) or an indium zinc oxide , layer (IZO layer). The transparent conductive layer 130 can have a thickness of 30-200 nm, for example 80 nm. The transparent conductive layer 130 can be formed by performing physical vapor deposition (PVD), such as sputtering or evaporation, and the evaporation can be electron beam evaporation, and the base pressure of the sputtering is about 10⁻⁵-10⁻⁶ torr, substantially high vacuum.

In addition, during the period of forming the doped amorphous Si layer 122, the intrinsic amorphous Si layer 124 and the transparent conductive layer 130, the doped amorphous Si layer 122, the intrinsic amorphous Si layer 124 and the transparent conductive layer 130 are kept in the vacuum environment without contacting air or atmosphere. Even, the doped amorphous Si layer 122, the intrinsic amorphous Si layer 124 and the transparent conductive layer 130 are formed in the same chamber, i.e. they are formed in situ.

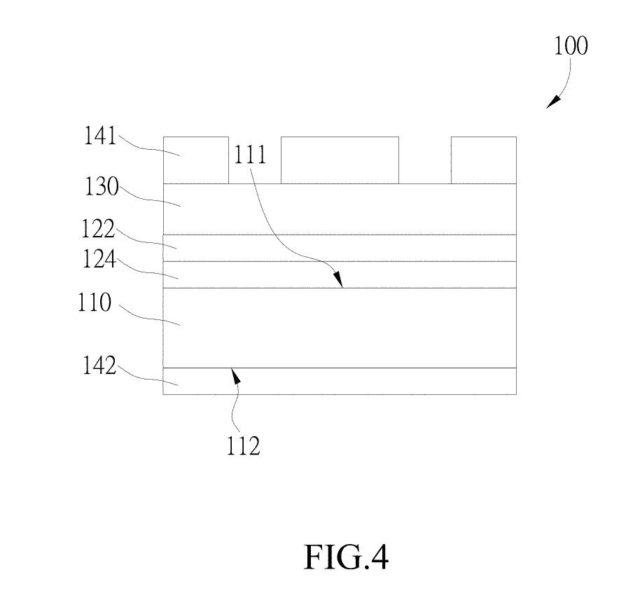

Still refer to FIG. 4. Next, a first electrode layer 141 is formed on the transparent conductive layer 130, and a second electrode layer 142 is formed on the second surface 112, wherein the crystalline Si substrate 110 is disposed between the first electrode layer 141 and the second electrode layer 142, and the second electrode layer 142 is formed after forming the first electrode layer 141. The first electrode layer 141 exposes at least one portion of the transparent conductive layer 130. For example, the first electrode layer 141 can have at least one opening for exposing the transparent conductive layer 130. Alternatively, the shape of the first electrode layer 141 can be a mesh, so as to expose the transparent conductive layer 130.

After forming the first electrode layer 141 and the second electrode layer 142, a layer structure of the HIT solar cell 100 has been formed substantially, wherein the HIT solar cell 100 comprises the crystalline Si substrate 110, the intrinsic amorphous Si layer 124, the doped amorphous Si layer 122, the transparent conductive layer 130, the first electrode layer 141 and the second electrode layer 142.

The first electrode layer 141 and the second electrode layer 142 can be formed by performing the electron beam evaporation. The HIT solar cell 100 comprises layers as follows: the intrinsic amorphous Si layer 124, the doped amorphous Si layer 122, the transparent conductive layer 130, the first electrode layer 141 and the second electrode layer 142, wherein theses layers are kept in the vacuum environment without contacting air or atmosphere before theses layers are formed. For example, these layers are formed in the same chamber, i.e. theses layers are formed in situ. Alternatively, these layers are formed in more than two chambers respectively, and these chambers are communicated with each other by flange, such that theses layers do not contact air or atmosphere before theses layers are formed.

After forming the first electrode layer 141 and the second electrode layer 142, rapid thermal annealing (RTA) is performed for the intrinsic amorphous Si layer 124, the doped amorphous Si layer 122 and the crystalline Si substrate 110 within the ambient atmosphere. The temperature of the RTA is 200-400 centigrade degrees, such as 220 centigrade degrees. Alternatively, temperature of the RTA is 400-600 centigrade degrees, such as 450 centigrade degrees. After the RTA is performed, the HIT solar cell 100 has been formed substantially.

The atmosphere gas comprises hydrogen gas, and the hydrogen gas is used to reduce the defects in the intrinsic amorphous Si layer 124 and the doped amorphous Si layer 122, such as dangling bonds, such that the probability of trapping charge carrier is decreased. In the embodiment, the atmosphere gas further comprises nitrogen gas. In the atmosphere gas, a concentration of the nitrogen gas is larger than that of the hydrogen gas. In other one embodiment, the atmosphere merely comprises hydrogen gas.

It is noted that, after the RTA is performed, the grain sizes of the intrinsic amorphous Si layer 124 and the doped amorphous Si layer 122 are still less than 5 nm, such that the intrinsic amorphous Si layer 124 and the doped amorphous Si layer 122 are still amorphous Si layers rather than monocrystalline or polycrystalline Si layers.

To sum up, the interface between the intrinsic amorphous Si layer and the crystalline Si substrate form a junction between the monocrystalline Si and the amorphous Si with different energy bands, so as to reduce the probability of trapping the charge carrier and to raise the open-circuit voltage. Furthermore, since the intrinsic amorphous Si layer and the doped amorphous Si layer are formed by performing the electron beam evaporation, compared with the chemical vapor deposition (CVD) which is used to form the convention solar cell, the cost of the electron beam evaporation is lower, and thus the manufacturing cost of the HIT solar cell can be reduced.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A method for manufacturing a Heterojunction with Intrinsic Thin layer (HIT) solar cell, at least comprising:
providing a crystalline Si substrate having a first surface and a second surface opposite to the first surface;
cleaning the first surface by using acidic liquid;
performing electron beam evaporation to sequentially form an intrinsic amorphous Si layer and a doped amorphous Si layer on the first surface, wherein the intrinsic amorphous Si layer contacts the doped amorphous Si layer and the crystalline Si substrate, and is disposed between the doped amorphous Si layer and the crystalline Si substrate, the intrinsic amorphous Si layer has a thickness of 5 nm to 50 nm, and the doped amorphous Si layer has a thickness of 10 nm to 100 nm;
forming a transparent conductive layer on the doped amorphous Si layer;
forming a first electrode layer on the transparent conductive layer, wherein the first electrode layer exposes at least one portion of the transparent conductive layer;
forming a second electrode layer on the second surface, wherein the crystalline Si substrate is disposed between the first electrode layer and the second electrode layer; and
after forming the first electrode layer and the second electrode layer, performing rapid thermal annealing for the intrinsic amorphous Si layer, the doped amorphous Si layer and the crystalline Si substrate in atmosphere gas, wherein the atmosphere gas comprises hydrogen gas.

2. The method for manufacturing the HIT solar cell according to claim 1, wherein the acidic liquid is composed of nitric acid, acetic acid and hydrofluoric acid.

3. The method for manufacturing the HIT solar cell according to claim 2, wherein a weight ratio of the nitric acid, the acetic acid and the hydrofluoric acid associated with the acidic liquid is 23:14:4.5.

4. The method for manufacturing the HIT solar cell according to claim 1, wherein cleaning the first surface by using the acidic liquid is to soak the crystalline Si substrate in the acidic liquid, and a time of soaking the crystalline Si substrate in the acidic liquid is 2-5 minutes.

5. The method for manufacturing the HIT solar cell according to claim 1, wherein a temperature of the rapid thermal annealing is 200-400 centigrade degrees.

6. The method for manufacturing the HIT solar cell according to claim 1, wherein a temperature of the rapid thermal annealing is 400-600 centigrade degrees.

7. The method for manufacturing the HIT solar cell according to claim 1, wherein the transparent conductive layer is formed by physical vapor deposition.

8. The method for manufacturing the HIT solar cell according to claim 7, wherein the physical vapor deposition is sputtering, and a base pressure of the sputtering is 10⁻⁵-10⁻⁶ torr.

9. The method for manufacturing the HIT solar cell according to claim 1, wherein a base pressure of the electron beam evaporation is less than 5×10⁻⁶ torr.

10. The method for manufacturing the HIT solar cell according to claim 1, wherein both of the first electrode layer and the second electrode layer are formed by the electron beam evaporation.

11. The method for manufacturing the HIT solar cell according to claim 1, wherein the atmosphere gas further comprises nitrogen gas, and in the atmosphere gas, a concentration of the nitrogen gas is larger than that of the hydrogen gas.
